(19) United States
(12) Patent Application Publication
(10) Pub. No.: US 2003/0003717 A1
(43) Pub. Date: Jan. 2, 2003

(54) Method for forming a dual damascene line

(76) Inventor: Chang-Woo Park, Cheongju-shi (KR)

Correspondence Address: MARSHALL, GERSTEIN & BORUN, 6300 SEARS TOWER, 233 SOUTH WACKER, CHICAGO, IL, 60606-6357, US

(21) Appl. No.: 10/178,007

(22) Filed: Jun. 21, 2002

(30) Foreign Application Priority Data
Jun. 21, 2001 (KR) 2001-35488

(51) Int. Cl. H01L 21/4763

(52) U.S. Cl. 438/638; 438/618

(57) ABSTRACT

A method for forming a dual damascene line, in which a via-hole contacting with a semiconductor substrate is formed during a line forming process in a dual damascene process, and a line hole for upper line is formed by etching with a fluorine gas containing a single carbon to prevent polymers from remaining on the boundary area between the line hole and the via-hole is prevented and the profile of the lines is improved to prevent an increase in the width of the lines.

### BACKGROUND OF THE DISCLOSURE

1. Field of the Disclosure

The disclosures relates generally to a method for forming a dual damascene line and, more particularly, to a method for forming a dual damascene line in which a via-hole contact a semiconductor substrate is formed during a line forming process in a dual damascene process, and a line hole for an upper line is formed by etching with a fluorine gas containing a single carbon, to prevent polymers from remaining on the boundary area between the line hole and the viahole.

2. Description of the Related Art

As the degree of integration of semiconductor devices increases, the width of the lines of the semiconductor substrate as well as that of the via-hole becomes a great concern in order to achieve high integration of conductive lines.

FIG. 1A through FIG. 1D are cross sectional views illustrating the consecutive steps of a conventional method for forming a dual damascene line.

As shown in FIG. 1A, a first etching stopper layer 20, a first insulation layer 30, a second etching stopper layer 40, and a second insulation layer 50 are formed consecutively on a semiconductor substrate 10. The first insulation layer 30 and the second insulation layer 50 are made of a silicon oxide material.

Then, a first photosensitive layer 60 is formed on the second insulation layer 50 and then patterned, and a via-hole 70 is formed by etching the first insulation layer 30 and the second insulation layer 50 to the upper side of the first etching stopper layer 20 using the photosensitive layer 60 as a mask, and then performing a cleaning process.

Then, as shown in FIG. 1B, the first photosensitive layer 60 is removed, and a second photosensitive layer 80 is patterned to form a line hole on the second insulation layer 50.

Then, a line hole 90 is formed in the second insulation layer 50 by etching it to the upper side of the second etching stopper line 40, and cleaning it.

As shown in FIG. 1C, the first etching stopper layer 20 and the second etching stopper layer 40, which are exposed to air, are removed by using the second photosensitive layer 80 as a mask, and then the second photosensitive mask 80 is removed.

Afterwards, as shown in FIG. 1D, the dual damascene line is formed by filling up the inner space of the via-hole 70 and the line hole 90 with a metal layer 95.

However, according to such a conventional method for forming a dual damascene line, the line hole is formed in the insulation layers, of which etching ratios are the same. The insulation layers are composed of the first insulation layer and the second insulation layer, and the etching process for forming the line hole has to be controlled by forming a nitride layer (i.e., is the etching stopper layer). Accordingly, the process for forming the line is complex.

Furthermore, as the permittivity of the nitride layer (i.e., is the etching stopper layer) is about 6ε to about 7ε, an insulation layer having a low dielectric constant K cannot be formed. Thus, the capacitance between the lines increases, deteriorating the electrical property of the semiconductor device.

FIG. 2A through FIG. 2D show the consecutive steps of another conventional method for forming a dual damascene line, which can solve the above-described problems existing in the method shown in FIG. 1A through FIG. 1D.

As shown in FIG. 2A, an etching stopper layer 10 and an insulation layer 120 are formed consecutively on a semiconductor substrate 100, and a first photosensitive layer (not shown) is formed and patterned.

Afterwards, a via-hole 130 is formed by etching the insulation layer 120 to the upper side of an etching stopper layer 110 by using a first photosensitive layer (not shown) as a mask, and then the first photosensitive layer (not shown) is removed and a cleaning process is performed.

Then, as shown in FIG. 2B, an anti-reflection layer 140 is formed on the result that the via-hole 130 is formed, and a second photosensitive layer 150 is also formed and patterned.

The anti-reflection layer 140, exposed to air, is removed by etching with a mixture of CHF₃ gas, CF₄ gas, and Ar gas by using the patterned second photosensitive layer 150 as a mask.

In such a situation, while the anti-reflection layer 140 is being removed, the anti-reflection layer 140 in the via-hole 130 is not removed completely, and as shown in FIG. 2B, a part of the anti-reflection layer 140 remains in the via-hole 130 with the shape of a spacer.

After that, as shown in FIG. 2C, a line hole 160 is formed in the insulation layer 120 by using a mixture of C₄F₈ gas, O₂ gas, and Ar gas under low pressure (below 100 mT) by using the patterned second photosensitive layer 150 as a mask.

In that situation, the fluorine gas C₄F₄ containing multiple carbons, which is used in forming the line hole 160, reacts chemically with the anti-reflection layer 140 remaining in the via-hole 130, to form a polymer 170 protruding upwardly at both ends of the opening of the via-hole 130.

Then, as shown in FIG. 2D, after removing the second photosensitive layer 150 and the anti-reflection layer 140, the etching stopper layer 110 is etched by using the insulation layer 120 as a mask, which is formed with the via-hole 130 and the line hole 160.

After that, the inner space of the via-hole 130 and the line hole 160 is filled with a metal layer 180 to form a dual damascene line.

However, according to this conventional method for forming the dual damascene line, the anti-reflection layer in the via-hole is not removed completely in the process for removing the anti-reflection layer, but remains in the inner sidewall of the via-hole with the shape of a spacer.

Consequently, the C₄F₄ gas (i.e., a the fluorine gas containing multiple carbons) reacts chemically with the anti-reflection layer remaining in the via-hole, to form a polymer protruding upward at both ends of the outer area of the via-hole. Therefore, there required an additional process for removing the polymer, which makes the process for forming the dual damascene line more complex.

Furthermore, if the amount of O₂ gas is increased during the etching process for forming the line hole in order to remove the polymer, the width of the line may increase.

### SUMMARY OF THE DISCLOSURE

The disclosure provides a method for forming a dual damascene line in which a via-hole in contact with a semiconductor substrate is formed during a line forming process and a line hole for upper line is formed by etching with a fluorine gas having a single carbon atom, whereby the polymers are prevented from remaining on the boundary area between the line hole and the via-hole, and as the edge area of the via hole is tilted, it is easy to fill the metal layer and, therefore, increase of width of the line can be prevented since the line profile is improved.

The disclosure provides a method for forming a dual damascene line, including the steps of: consecutively forming a via-hole by forming an etching stopper layer and an insulation layer on a semiconductor substrate, forming and patterning a first photosensitive layer, and etching the insulation layer to an upper side of the etching stopper layer by using the first photosensitive layer as a mask; removing the photosensitive layer, forming an anti-reflection layer, forming and patterning a second photosensitive layer, and removing the anti-reflection layer with etching by using the second photosensitive layer as a mask; forming a line hole by etching the insulation layer with an etching gas that is a mixture of CH₃ gas, CF₄ gas, and Ar gas by using the second photosensitive layer as a mask; and removing the second photosensitive layer and the anti-reflection layer, etching the etching stopper layer by using the insulation layer formed with the via-hole as a mask, and filling up an inner space of the via-hole and the line hole with a metal layer.

According to the disclosure, the line hole is formed by etching with fluorine gas containing a single carbon atom, preferably at high pressure, so the polymer does not remain on the boundary between the line hole and the via-hole.

### BRIEF DESCRIPTION OF THE DRAWINGS

Other aspects of the disclosure will become apparent from the following description of embodiments with reference to the accompanying drawing in which:

FIG. 1A through FIG. 1D are cross sectional views for illustrating the consecutive steps of a conventional method for forming a dual damascene line;

FIG. 2A through FIG. 2D are cross sectional views for illustrating the consecutive steps of another conventional method for forming a dual damascene line; and

FIG. 3A through FIG. 3D are cross sectional views for illustrating consecutively a method for forming a dual damascene line according to the disclosure.

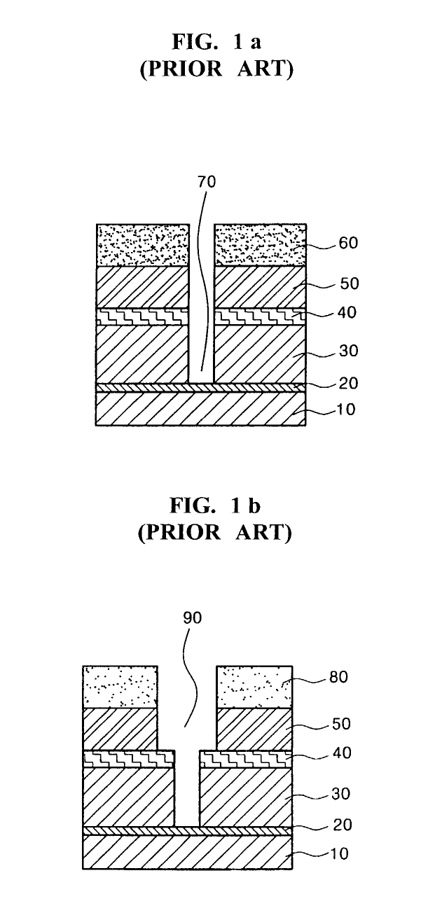

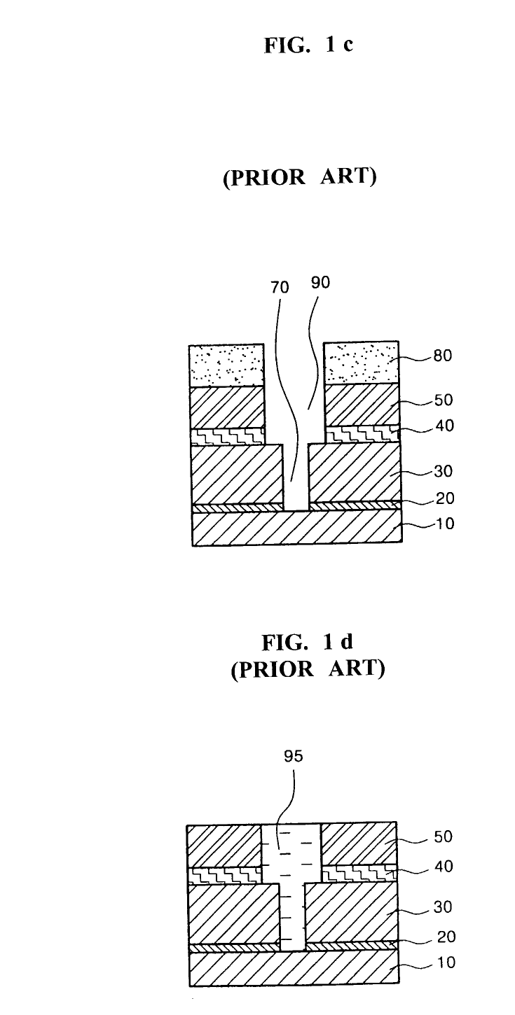

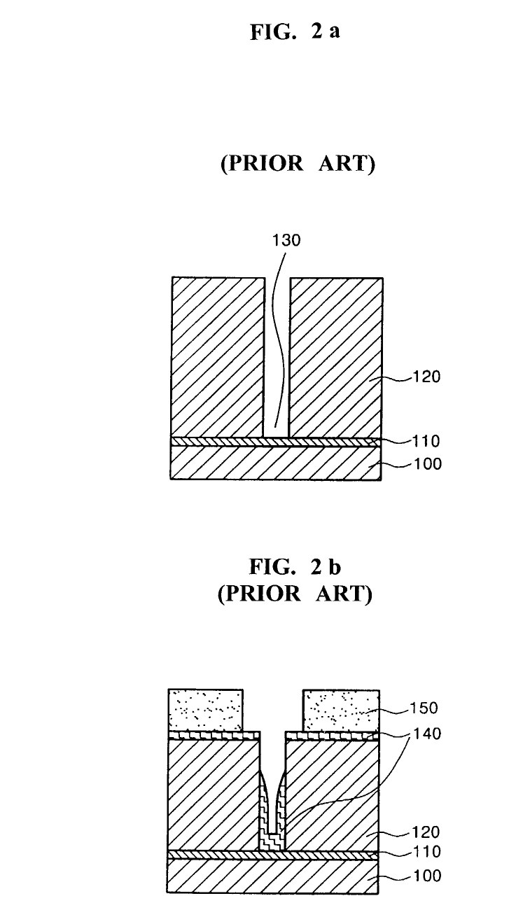

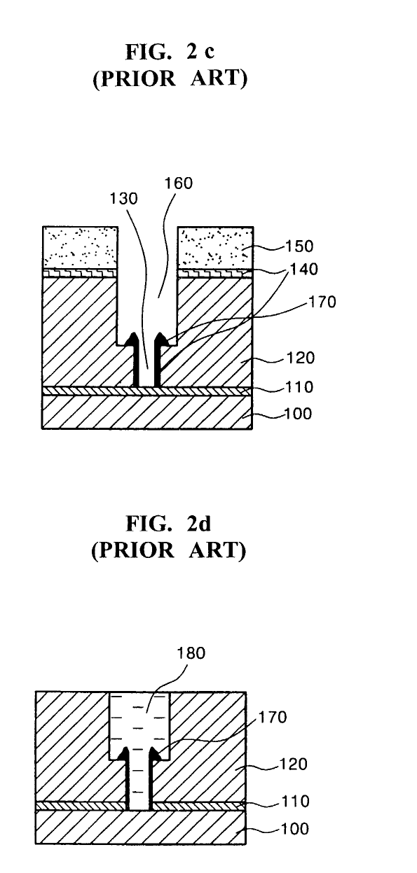

### DESCRIPTION OF THE PREFERRED EMBODIMENT

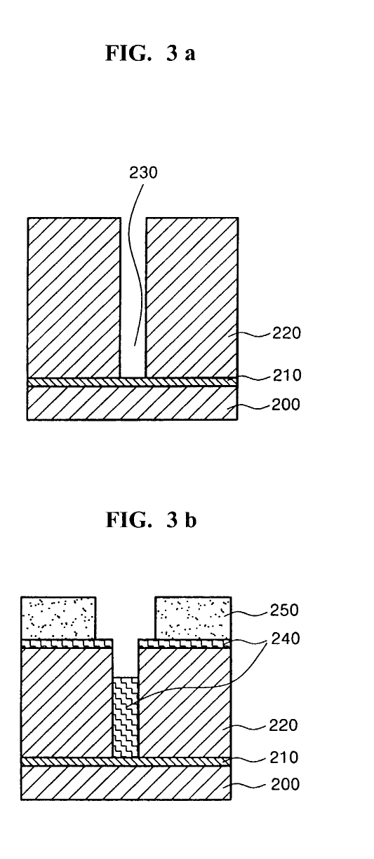

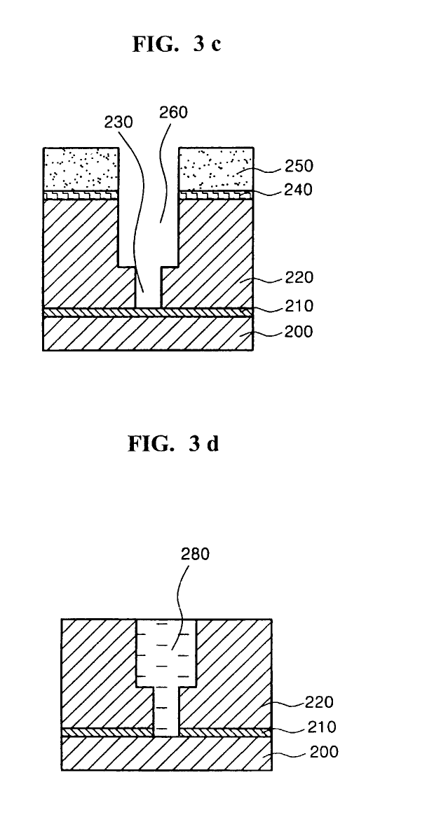

As shown in FIG. 3A, an etching stopper layer 210 and an insulation layer 220 are consecutively formed on a semiconductor substrate 200, and a first photosensitive layer (not shown) is formed and patterned.

In FIG. 3A, the etching stopper layer 210 is made of a nitride material that has a superior selectivity of etching with respect to the insulation layer 220 made of a silicon oxide layer, in order to prevent damage to the semiconductor substrate 200 caused by etching while a via-hole is subsequently formed on the insulation layer 220 made of a silicon oxide.

After that, a via-hole 230 is formed by dry etching to the upper side of the etching stopper layer 210 with a mixture of C₄F₈ gas, O₂ gas, and Ar gas at a pressure of about 10 mT to about 100 mT by using the patterned first photosensitive layer (not shown) as a mask.

The mixture used in the dry etching is composed of the C₄F₈ gas at about 10 sccm to about 30 sccm, O₂ gas at about 10 sccm to about 40 sccm, and Ar gas at about 300 sccm to about 500 sccm.

After the first photosensitive layer (not shown) is removed, a wet cleaning process is performed using a cleaning liquid that is a mixture of NH₄OH, CH₃COOH, and H₂O mixed at the ratio of 2:3:30.

Meanwhile, the via-hole forming process can be performed by two etching steps.

First, the via-hole 230 is formed by etching with a mixture of C₄F₈ gas at about 10 sccm to about 30 sccm, O₂ gas at about 10 sccm to about 30 sccm, and Ar gas at about 300 sccm to about 500 sccm at a pressure of about 30 mT to about 50 mT by using a patterned photosensitive layer (not shown) as a mask.

Then, the via-hole 230 is formed by additional etching with a mixture of CHF₃ gas at about 10 sccm to about 50 sccm, O₂ gas at about 10 sccm to about 50 sccm, and Ar gas at about 200 sccm to about 800 sccm in the pressure of about 10 mT to about 100 mT by using the patterned photosensitive layer (not shown) as a mask, whereby the via-hole 230 having a superior profile is formed.

Then, as shown in FIG. 3B, an anti-reflection layer 240 is formed on the result formed with the via-hole 230, and a second photosensitive layer 250 is formed and patterned.

Next, the anti-reflection layer 240 exposed to air is removed by using the patterned second photosensitive layer 250 as a mask.

In that situation, the anti-reflection layer 240 is formed by etching with a mixture of CHF₃ gas at about 10 sccm to about 100 sccm, CF₄ gas at about 100 sccm to about 200 sccm, and Ar gas at about 1000 sccm to about 2000 sccm, at a pressure of about 1000 mT to about 2000 mT.

After that, as shown in FIG. 3C, a line hole 260 is formed on the insulation layer 220 by etching with a mixture of CHF₃ gas which is a fluorine gas containing a single carbon, CF₄ gas, and Ar gas, in a high pressure of about 500 mT to about 1500 mT, by using the patterned second photosensitive layer 250 as a mask.

In that situation, the mixture is composed of the CHF₃ gas at about 10 sccm to about 100 sccm, the CF₄ gas at about 100 sccm to about 200 sccm, and the Ar gas at about 1000 sccm to about 2000 sccm.

As the consequence, polymer generation around the opening of the viahole 230 by the chemical reaction between a multiple carbon contained in the etching gas and the anti-reflection layer 240, is prevented.

Next, as shown in FIG. 3D, after removing the second photosensitive layer 250 and the anti-reflection layer 240, the etching stopper layer 210 is etched by using the insulation layer 220 formed with the via-hole 230 and the line hole 260 as a mask.

In such a situation, the etching stopper layer 210 is etched by using the mixture of CHF₃ gas at about 10 sccm to about 50 sccm, CF₄ gas at about 10 sccm to about 50 sccm, and Ar gas at about 200 sccm to about 800 sccm, in the pressure of about 10 mT to about 100 mT.

Then, the inner space of the via-hole 230 and line hole 260 is filled up with metal layer 280 to form a dual damascene line.

According to the method for forming a dual damascene line of the disclosure, since the line hole for upper line is formed by etching with a fluorine gas containing a single carbon in a high pressure, the generation of polymer on the boundary area between the line hole and the via-hole can be prevented, and it is easy to fill up the metal layer at the edge area of the via-hole is tilted.

Furthermore, as the result, the line profile is improved to prevent the increase of the width of the line.

Although the preferred embodiment of the method has been described, it will be understood by those skilled in the art that the scope of the disclosed method should not be limited to the described preferred embodiment, but various changes and modifications can be made within the spirit and the scope of the disclosure.

What is claimed is:

1. Method for forming a dual damascene line, comprising the steps of:
forming a via-hole by consecutively forming an etching stopper layer and an insulation layer on a semiconductor substrate, forming and patterning a first photosensitive layer, and etching the insulation layer to an upper side of the etching stopper layer using the first photosensitive layer as a mask;
removing the first photosensitive layer, forming an anti-reflection layer, forming and patterning a second photosensitive layer, and removing the anti-reflection layer with dry etching by using the second photosensitive layer as a mask;
forming a line hole by etching the insulation layer with an etching gas comprising a mixture of CH₃ gas, CF₄ gas, and Ar gas using the second photosensitive layer as a mask; and
removing the second photosensitive layer and the anti-reflection layer, etching the etching stopper layer using the insulation layer formed with the via-hole as a mask, and filling up an inner space of the via-hole and the line hole with a metal layer.

2. The method of claim 1, wherein the step of forming the via-hole comprises etching with a mixture of C₄F₈ gas, O₂ gas, and Ar gas at a pressure of 10 mT to 100 mT.

3. The method of claim 2, wherein the mixture for forming the via-hole comprises 10 sscm to 30 sccm C₄F₈ gas, 10 sccm to 40 sccm O₂ gas, and 300 sccm to 500 sccm Ar gas.

4. The method of claim 1, wherein the line hole forming step comprises etching at a high pressure of 500 mT to 1500 mT.

5. The method of claim 4, wherein the mixture for forming the line hole comprises 10 sccm to 100 scem CHF₃ gas, 100 sccm to 200 sccm CF₄ gas, and 1000 sccm to 2000 sccm Ar gas.

6. The method of claim 1, comprising etching the stopper layer with a mixture of CHF₃ gas, O₂ gas, and Ar gas at a pressure of 10 mT to 100 mT.

7. The method of claim 6, wherein the mixture for etching the stopper layer comprises 10 sccm to 50 sccm CHF₃ gas, 10 sccm to 50 sccm CF₄ gas, and 200 sccm to 800 sccm Ar gas.

8. The method of claim 1, comprising etching the anti-reflection layer with a mixture of CHF₃ gas, CF₄ gas, and Ar gas at a pressure of 1000 mT to 2000 mT.

9. The method of claim 8, wherein the mixture for etching the anti-reflection layer comprises 10 sccm to 100 sccm CHF₃ gas, 150 sccm to 200 sccm CF₄ gas, and 1000 sccm to 2000 sccm Ar gas.

10. The method of claim 1, wherein the step of forming the via-hole comprises two etching steps.

11. The method of claim 10, comprising performing a first etching step for forming the via-hole with a mixture of C₄F₈ gas, O₂ gas, and Ar gas at a pressure of 30 mT to 50 mT.

12. The method of claim 11, wherein the mixture for the first etching step comprises 10 sccm to 30 sccm C₄F₈ gas, 10 scem to 30 sccm O₂ gas, and 300 sccm to 500 sccm Ar gas.

13. The method of claim 10, comprising performing a second etching step for forming the via-hole with a mixture of CHF₃ gas, O₂ gas, and Ar gas at a pressure of 10 mT to 100 mT.

14. The method of claim 13, wherein the mixture for the second etching step comprises 10 sccm to 50 sccm CHF₃ gas, 10 sccm to 50 sccm O₂ gas, and 200 sccm to 800 sccm Ar gas.
